(19) United States
(12) Patent Application Publication
(10) Pub. No.: US 2014/0158535 A1
(43) Pub. Date: Jun. 12, 2014

(54) Electrochemical Amperometry-Based Sensor Combined With Long-Range Radio Communication For Measurement Of Analytes

(71) Applicant: Jonathan Javitt, Bethesda, MD (US)

(72) Inventor: Jonathan Javitt, Bethesda, MD (US)

(21) Appl. No.: 13/707,872

(22) Filed: Dec. 7, 2012

(51) Int. Cl. G01N 27/28; H05K 13/00

(52) U.S. Cl. CPC G01N 27/28; H05K 13/0023
USPC 204/406; 29/600; 29/601

(57) ABSTRACT

The methods and systems according to the present invention overcome the high-frequency radiation and thermal interferences on an electrochemical sensor combined with long range radio communication. A Faraday cage is used to shield the sensor from the radiation in one embodiment. In another embodiment, a controller is installed between the sensor and the antenna to deactivate the antenna emission when the electrochemical sensor is conducting measurement. To control thermal interference, the temperature rise is controlled. The battery temperature is monitored and charging cycle is controlled. The temperature rises can also be avoided via intermittent use of the radio, heat sink strategies to direct heat away from the radio circuitry, and radio module construction designed to minimize heat emission. The present invention discloses an electrochemical sensor combined with a long range radio communication that has an improved accuracy due to having a better control of high frequency radiation and thermal interferences.

### CROSS-REFERENCE

This is a continuation-in-part application to the U.S. application Ser. No. 13/212,171, filed on Aug. 17, 2011. Priority is claimed from said application, and said application is hereby incorporated by reference.

### BACKGROUND OF THE INVENTION

1. Field of the Invention

The present invention relates to an electrochemical sensor, and more particularly to an electrochemical sensor combined with long range radio communication and a system and method for controlling high frequency radiation interference and thermal interference.

2. Description of Related Art

Amperometry-based electrochemical sensors are well known to those with ordinary skill in the in the art (see Bard, A. J.; Faulkner, L. R. Electrochemical Methods: Fundamentals and Applications, 2^{nd} ed.; Wiley: New York, N.Y., USA, 2001). Similarly, the concept of combining such sensors with long-range radio communication capability is widely described (see Sensors 2011, 11, 8593-8610).

Electrochemical sensors generate microvolt to millivolt-level signals that may be perturbed by high-frequency radiation, such as that emitted by the antenna of a long-range radio, for example cellular radio. Since the amplitude of the signal from the sensor is used to calculate the concentration of the analyte, any alteration of this signal will introduce measurement bias.

The rate of Electrochemical reactions is highly sensitive to the ambient temperature at which the reaction occurs. Therefore, most known electrochemical sensors are combined with a temperature sensor inside the device housing to provide a correction factor that is needed to calculate the concentration of the analyte. Devices that utilize long range radio communication are likely to contain one or more elements that generate thermal energy. These elements include rechargeable batteries that may emit heat during their charging cycles, radio circuitry that characteristically emits heat, and color display screens that may emit heat. Without proper controls, this thermal energy may reach the temperature sensor and cause the temperature measured by said sensor to be higher than the true ambient temperature outside the device housing.

No prior patents, however, address two key enabling concepts: 1) control of high-frequency radiation interference, and 2) control of thermal interference. Therefore, there exists a need for a method and system to control high frequency radiation interference and thermal interference on an electrochemical sensor combined with long range radio as well as an electrochemical sensor combined with long range radio of which the high frequency radiation interference and thermal interference is controlled.

### SUMMARY OF THE INVENTION

The methods and systems according to the present invention overcome the high-frequency radiation interference mentioned in the foregoing section. In one embodiment of the present invention, the system comprises a Faraday cage for shielding all elements of the sensor from high frequency radiation. Other types of shielding may also be used for the same purpose. A second embodiment developed to reduce the high frequency radiation interference comprises a controller for controlling the antenna emission. The controller deactivates antenna emission when the electrochemical sensor conducts a measurement and reactivates antenna emission when the measurement is completed and ready for data transmission.

Following methods and systems according to the present invention prevents thermal energy from reaching the temperature sensor and causing the temperature measured by said sensor to be higher than the true ambient temperature outside the amperometry-based electrochemical sensor device housing. The first approach to solve the problem is to put the temperature sensor in a location that has good ventilation. In one embodiment, the temperature sensor is located at a ventilated portion of the enclosure. In another embodiment, the temperature sensor is located outside the enclosure. The temperature sensor may be an external probe that is located on a permanent stalk or a removable sensor.

A second approach to prevent thermal energy from reaching the temperature sensor and cause inaccurate analytical result is to avoid heat generation and temperature rise. This can be achieved by monitoring of battery temperature and use of pulse-width charging and/or control of charging voltage. In one embodiment, the system comprises a temperature monitor, control software and controller to control current charging cycle from the battery charger to the battery. The software is programmable and target temperature and cutoff can be input by a user. To avoid temperature rise can also be achieved via intermittent use of the radio, heat sink strategies to direct heat away from the radio circuitry, and radio module construction designed to minimize heat emission.

The method of or arrangement of wiring or connecting the above electronic components and mounting them will be well known to those with ordinary skill in the electronic and mechanical arts.

The more important features of the invention have thus been outlined in order that the more detailed description that follows may be better understood and in order that the present contribution to the art may better be appreciated. Additional features of the invention will be described hereinafter and will form the subject matter of the claims that follow.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

The foregoing has outlined, rather broadly, the preferred feature of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention and that such other structures do not depart from the spirit and scope of the invention in its broadest form.

### BRIEF DESCRIPTION OF THE DRAWINGS

Other aspects, features, and advantages of the present invention will become more fully apparent from the following detailed description, the appended claim, and the accompanying drawings in which similar elements are given similar reference numerals.

FIG. 1 is a diagram of an exemplary Amperometry-based electrochemical sensor coupled with long-range radio communication.

FIG. 2 is a diagram of a first embodiment that can control high frequency radiation interference on an electrochemical sensor coupled with long-range radio communication.

FIG. 3 is a diagram of a second embodiment that can control high frequency radiation interference on an electrochemical sensor coupled with long-range radio communication.

FIG. 4 is a diagram of a first embodiment that can control thermal interference on an electrochemical sensor coupled with long-range radio communication.

FIG. 5 is a diagram of a second embodiment that can control thermal interference on an electrochemical sensor coupled with long-range radio communication.

### DESCRIPTION OF THE PREFERRED EMBODIMENT

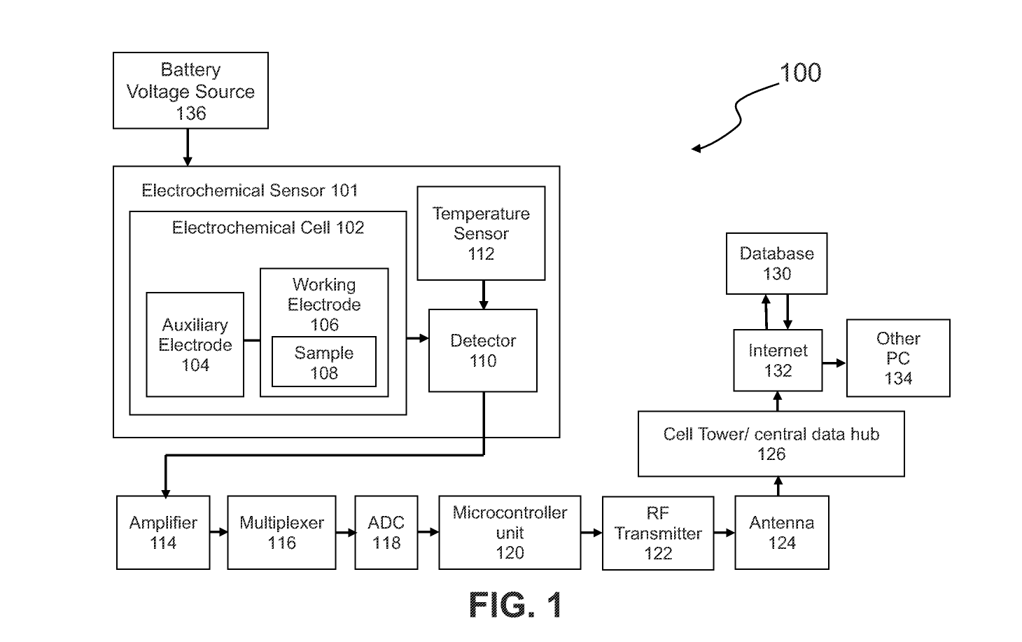

Referring to FIG. 1, there is disclosed a diagram of an exemplary Amperometry-based electrochemical sensor coupled with long-range radio communication capability. As shown in FIG. 1, device 100 includes an amperometry-based electrochemical sensor 101 which may comprise a two or three electrode cell 102. In this figure a cell 102 with two electrodes 104 and 106 is shown. When a sample 108 reacts within the electrochemical cell 102, the electrical current (signal) generated and measured by the detector 110 is further amplified by the amplifier 114 and output through the multiplexer 116 and converted to digital form by the ADC 118. The digital signals are then processed by microcontroller unit 120 and transmitted to a cell tower and from there to a cellular data hub 126 via radio frequency (RF) transmitter 122 and antenna 124. RFtransmitter 122 generates a radio frequency alternating current, with the aid of the antenna 124, produces radio. The data can be uploaded to a database 130 over the internet 132, allowing remote access by other users 134. The battery 136 provides voltage source for the electrochemical sensor. The electrical current (signal) generated and measured theoretically should be proportional to the concentration of the analyte. However, the measurement may be affected by at least two factors as described in the foregoing sections. First, the measurement may be biased by the high frequency radiation interference. Secondly, the measurement may be biased by the thermal interference.

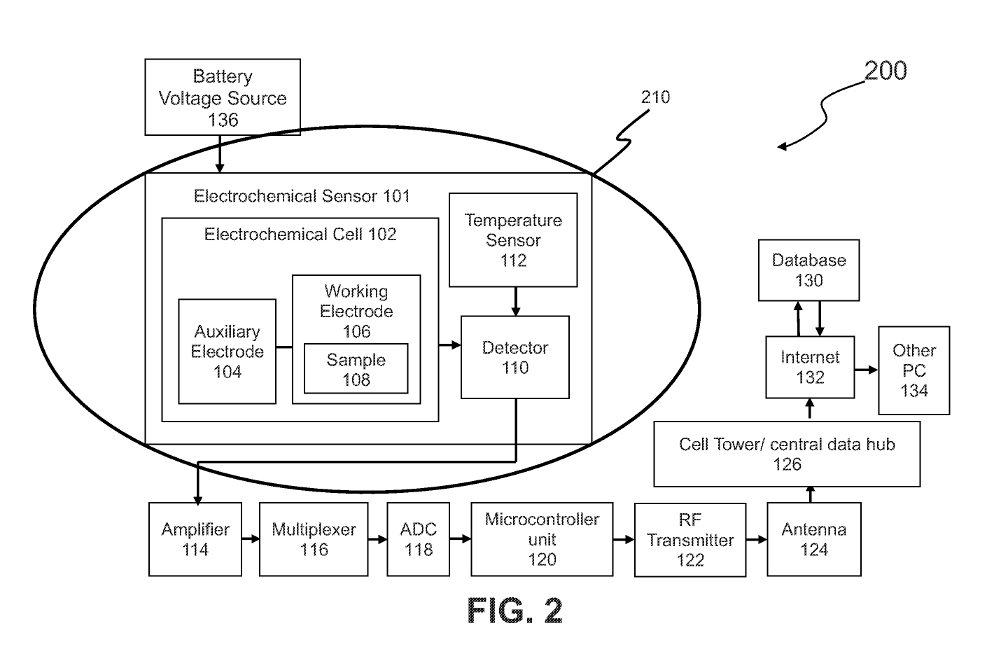

The foregoing background paragraphs presents the problems, the accuracy of analysis can be affected by the interference from high frequency radiation. Thus an effort of the present invention is made to shield all elements of the sensor from the high frequency radiation. A Faraday cage or shield is known in the art an enclosure formed by conducing material or by a mesh of such material. Such an enclosure blocks out external static and non-static electric fields. A Faraday cage is used to protect electronic equipment from lightning strikes, electrostatic discharges, and even radiation. Therefore, in one of the preferred embodiments 200 as disclosed in FIG. 2, a Faraday cage 210 is set up to shield all elements of the sensor 101 from high frequency radiation generated by the antenna 124. The Faraday cage is commercially available and known to those with ordinary skill in the art.

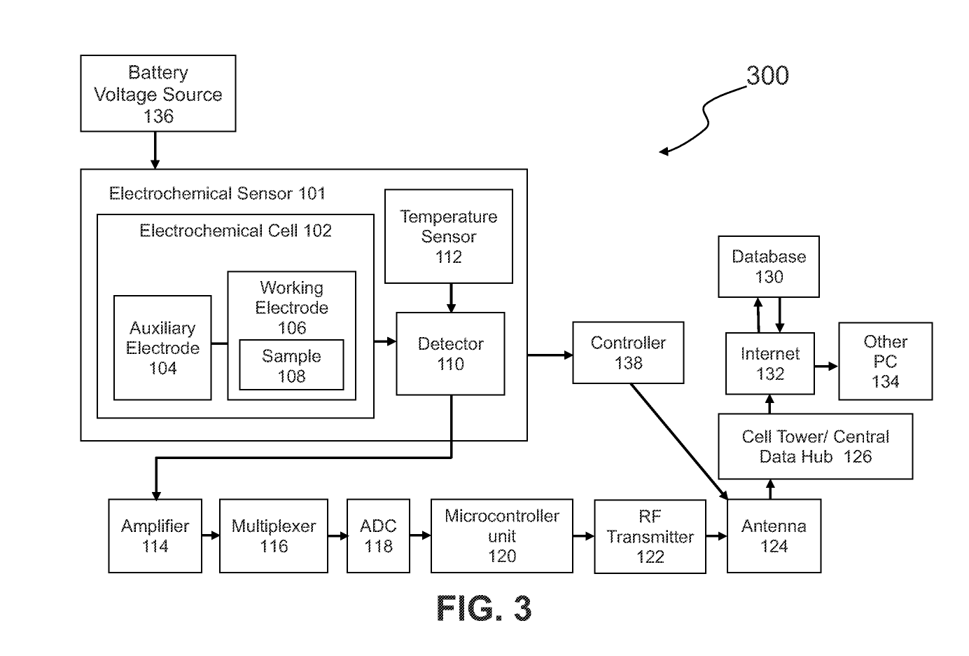

Because the high frequency radiation interference comes from the antenna electrically connected to the sensor for transmitting digital signal in the form of radio wave. A fundamental solution to minimize high frequency radiation is to stop transmission of radio wave when the electrochemical measurement is performed. Therefore, another preferred embodiment 300 is to set up a controller 138 between the electrochemical sensor 101 and the antenna 124 as disclosed in FIG. 3. The controller 138 may be placed in other locations between the electrochemical sensor 101 and the antenna 124. When the electrochemical sensor 101 is conducting an electrochemical measurement of a sample, the controller 138 will deactivate the antenna 124 emission, and thus the electrochemical measurement will not be interfered by the radio frequency. After the measurement is completed, the controller 138 will reactivate the antenna 124.

Alternatively, the antenna emission may also be controlled by a circuit switch between the RF transmitter 122 and the antenna 124. When the electrochemical sensor 101 is conducting a measurement, the circuit will be break off so that the antenna 124 is deactivated. After the measurement is completed, the circuit will be reconnected to reactivate the antenna 124.

The foregoing background paragraphs also presents the problems that the accuracy of analysis can be affected by thermal interference. The rate of electrochemical reactions is highly sensitive to the ambient temperature at which the reaction occurs. Therefore, most known electrochemical sensors are combined with a temperature sensor inside the device housing to provide a correction factor that is needed to calculate the concentration of the analyte.

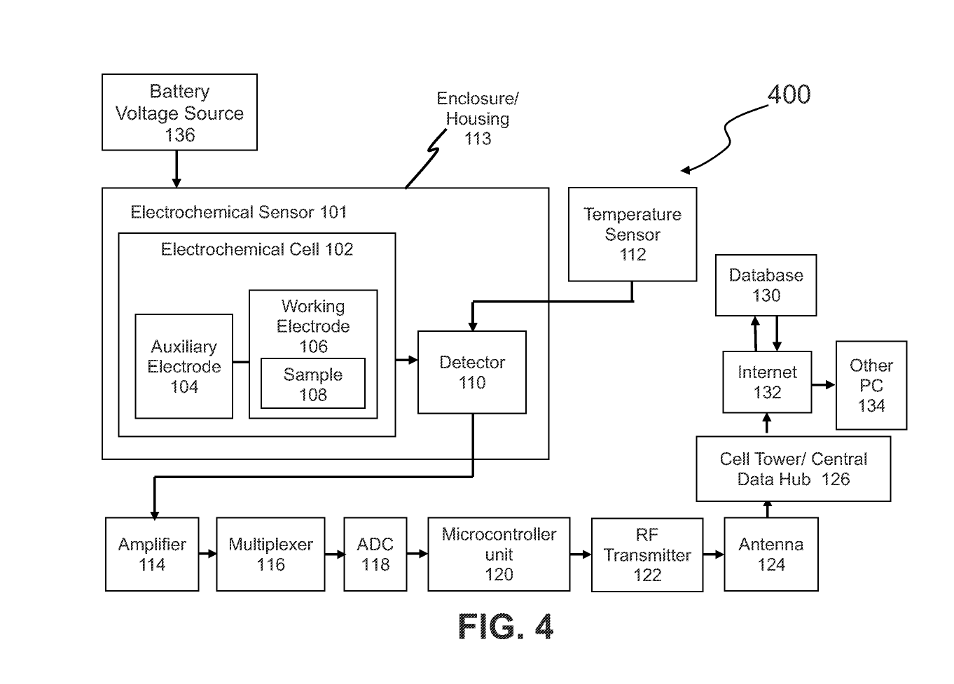

In order to accurately provide a correction factor the temperature sensor should not be affected by the heat generated from battery recharge or radio circuitry or other sources of heat. Therefore, the temperature sensor 112 for the electrochemical sensors 101 (amperometric sensors) may be located at a ventilated portion of the amperometric sensor enclosure 113. The temperature sensor 112 may be installed at a location outside of the amperometric sensor enclosure 113 in an alternate embodiment 400 as disclosed in FIG. 4. The temperature sensor 112 may be located at a probe located outside the enclosure 113.

Usually recharging of a battery using a battery charger potentially produces thermal energy affecting accuracy of electrochemical analysis. A fundamental approach to control thermal interference is to reduce heat generated by charging of a battery. Set up and arrangement of temperature control battery recharge is a technology known to those with ordinary skill in the art.

An example of a system for charging a rechargeable battery supplies controlled by temperature may be found in U.S. Pat. No. 7,521,897, titled “Battery charge temperature control”, issued on Apr. 21, 2009 to Wolf et al., which is herein incorporated by reference. The object of the invention disclosed in U.S. Pat. No. 7,521,897 is to minimize the performance degradation of the battery caused by high temperature and high voltage levels due to charging of battery while the object of the present invention is to control the thermal energy interfering the accuracy of an electrochemical analysis.

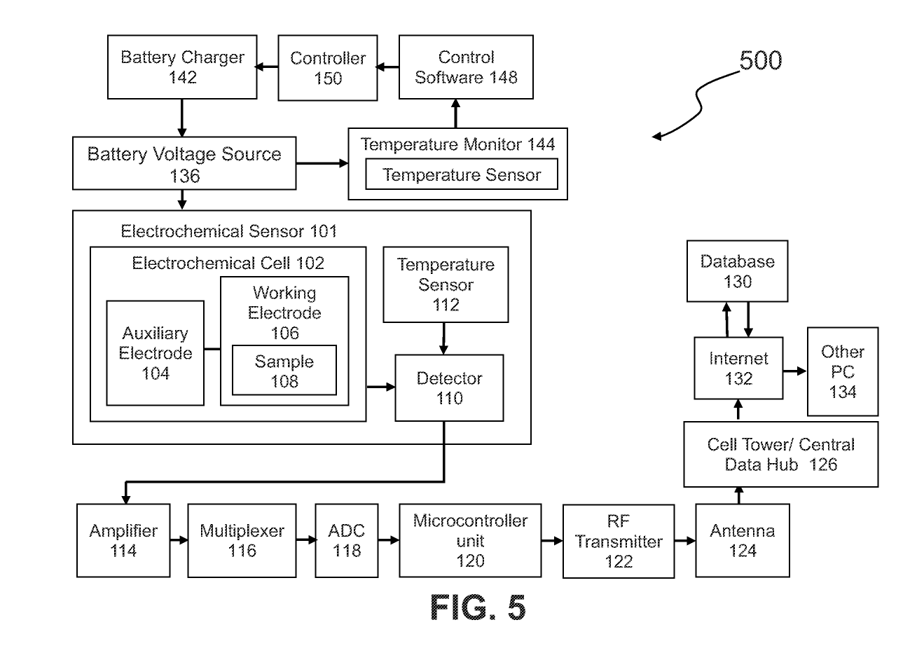

As shown in FIG. 5, the embodiment 500 to control the thermal interference caused by battery charging includes a temperature monitor 144 which may have a temperature sensor 146, such as a thermistor. Temperature monitor 144 may continuously (or periodically) monitor the temperature associated with battery 138. The embodiment will also include control software 148 and controller 150 for controlling battery charger 142. The control software 148 has user interface for user to input the target temperature and cut off values. Control software 148 controls the operation of controller 150 based on temperature information collected from temperature monitor 144 and target temperature and cutoff set in the software 148 to control the current supplied from the battery charger 142 to the battery 136 via an integrated circuit in the controller 150. The software 148 determines when the supplied current matches a value corresponding to the cutoff parameter and stops further supply of the supplied current to the battery 136 when the supplied current matches the value corresponding to the current cutoff parameter. The temperature cut off may be set at +/− 2 degrees Fahrenheit (F) of the target temperature. If the temperature sensor 142 measured a temperature above +2 degrees F. of the target temperature, the recharge of battery 136 will be turned off. If the temperature is below −2 degree F. of the target temperature, the voltage charger 142 will start to charge the battery 136. The particular target temperature and cutoff set in control software 148 may be programmable based on one or more factors associated with battery 136. For example, one set of current cutoff and temperature parameters may be provided for Li-ion batteries and another set of parameters may be provided for Li-poly batteries.

In another embodiment, pulse width modulation battery charger is used to charge battery in order to minimize thermal interference. Pulse width modulation battery chargers use pulse technology in which a series of voltage of current pulses is fed to the battery. Pulse Width Modulation (PWM) Battery Charging is one of the newer battery charging algorithms in charge battery chargers. A PWM charge regimen includes on and off cycles in quick repetition. By using PWM battery charging instead of constant charging, the heat generated by the charging process is reduced. Several kinds of pulse charging are patented (see U.S. Pat. No. 5,633,574). PWM battery chargers are available in the market place.

Radio circuits when functioning also generates heat, and thus, by turning off the radio circuits when not in need and turns on when in need can prevent internal temperature elevations.

Other conventional method known to those with ordinary skill in the electronic and mechanical arts for preventing internal temperature elevations include a heat sink. Heatsinks are used in many pieces of electronics equipment to ensure that heat can be removed from pieces of equipment or particular components within them. A heatsink absorbs and dissipates heat from an electronic component. A metal base (aluminum PCB) or thermal interface material, is brought into contact with the components' surface. Temperature is reduced through increased thermal mass and heat dissipation (conduction and convection). The most common heat sink material is aluminum alloys. Copper is also used as heat sink material. Composite material can be used for heat sink material.

1. The thermal interference control can be achieved by using the design of an active heat-sink antenna for radio-frequency transmitter (see IEEE Transactions on Advanced Packaging, 2010, 33, 1, 139-146). The antenna achieves electromagnetic and thermal functions by offering a suitable radiating pattern for transmission as high efficiency to remove the dissipated power within the transmitter by heat exchange to the surrounding medium. Of course, the internal temperature elevations can be prevented by having a radio module construction designed to minimize heat emission.

The method of or arrangement of wiring or connecting the above electronic components and mounting them will be well known to those with ordinary skill in the electronic and mechanical arts.

While there have been shown and described and pointed out the fundamental novel features of the invention as applied to the preferred embodiments, it will be understood that the foregoing is considered as illustrative only of the principles of the invention and not intended to be exhaustive or to limit the invention to the precise forms disclosed. Obvious modifications or variations are possible in light of the above teachings. The embodiments discussed were chosen and described to provide the best illustration of the principles of the invention and its practical application to enable one of ordinary skill in the art to utilize the invention in various embodiments and with various modifications as are suited to the particular use contemplated All such modifications and variations are within the scope of the invention as determined by the appended claims when interpreted in accordance with the breadth to which they are entitled.

What is claimed is:

1. An electrochemical sensor combined with long-range radio communication comprises: an electrochemical sensor, a radio frequency (RF) transmitter, an antenna, a battery, a battery charger, a computer, means for controlling high frequency radiation interference and means for controlling thermal interference.

2. The system of claim 1, wherein the electrochemical sensor conducts measurement of electrical current signal generated by a chemical reaction of a sample, the electrical current signal is converted to digital form and communicated to the local computer through the RF transmitter and antenna via a radio wave emission.

3. The sensor of claim 1, wherein the means for controlling high frequency radiation interference comprises a Faraday cage which shields the electrochemical sensor from high frequency radiation interference generated by the radio frequency and antenna.

4. The sensor of claim 1, wherein the means for controlling high frequency radiation interference comprises a controller which controls the deactivation and activation of antenna emission, the antenna emission is deactivated when the electrochemical sensor is conducting measurement and reactivated when the measurement is completed.

5. The sensor of claim 1, wherein the electrochemical sensor comprises an electrochemical cell; a detector; a housing which encloses the electrochemical cell and the detector, and a temperature sensor for providing a correction factor that is needed to calculate the concentration of a sample analyst; wherein the temperature sensor is located outside the housing.

6. The sensor of claim 1, wherein the electrochemical sensor comprises an electrochemical cell; a detector; a housing which encloses the electrochemical cell and the detector, and a temperature sensor for providing a correction factor that is needed to calculate the concentration of a sample analyst; wherein the temperature sensor is located at a ventilated portion within the housing.

7. The sensor of claim 1, wherein the means for controlling thermal interference comprises a temperature monitor, a control software, and a controller for controlling battery charger, the temperature monitor has a temperature sensor for monitoring the battery temperature, the control software is programmable and has a user interface for the user to input a target temperature and a cutoff value to control the controller, the controller has an integrated circuit connected to the battery charger.

8. The sensor of claim 7, wherein the control software determines whether the controller should trigger battery charger based on the temperature collected from the temperature monitor and the target temperature and cutoff values, when the collected temperature is below the lower limit of the cutoff values, the battery charger is turned on by the controller and when the collected temperature reaches the upper limit of the cutoff values, the battery charger is turned off.

9. The sensor of claim 1, wherein the battery charger utilizes pulse technology.

10. The sensor of claim 1, wherein the means for controlling thermal interference comprises a heatsink for absorbing and dissipating heat from radio circuitry.

11. The sensor of claim 1, wherein the means for controlling thermal interference comprises a controller to control intermittent use of the radio.

12. The sensor of claim 1, wherein the means for controlling thermal interference comprises a radio module construction which is designed to minimize heat emission.

13. The sensor of claim 1, wherein the means for controlling thermal interference comprises an active heat-sink antenna for radio-frequency transmitter.

14. A method of improving accuracy of an electrochemical sensor combined with long-range radio communication comprises means for controlling high frequency radiation interference and means for controlling thermal interference.

15. The method of improving accuracy of claim 14, wherein the means for controlling high frequency radiation interference comprises installing a Faraday cage to shield the electrochemical sensor.

16. The method of improving accuracy of claim 14, wherein the means for controlling high frequency radiation interference comprises placing a controller between the electrochemical sensor and the antenna, the controller deactivates the antenna emission when the electrochemical sensor is conducting measurement.

17. The method of improving accuracy of claim 14, wherein the means for controlling high frequency radiation interference comprises installing a temperature sensor which is used for providing a correction factor that is needed to calculate the concentration of a sample analyst at a location that has good ventilation.

18. The method of improving accuracy of claim 14, wherein the means for controlling thermal interference comprises controlling battery charging cycle by using a temperature monitor to monitor the battery temperature and a software to control the charging cycle of the battery.

19. The method of improving accuracy of claim 14, wherein the means for controlling thermal interference comprises installing a battery charger utilizing pulse technology.

20. The method of improving accuracy of claim 14, wherein the means for controlling thermal interference comprises installing a heatsink to absorb and dissipate heat from radio circuitry.

21. The method of improving accuracy of claim 14, wherein the means for controlling thermal interference comprises installing a temperature sensor outside the electrochemical sensor housing.

22. The method of improving accuracy of claim 14, wherein the means for controlling thermal interference comprises installing a controller for controlling intermittent use of the radio.

23. The method of improving accuracy of claim 14, wherein the means for controlling thermal interference comprises installing an active heat-sink antenna for radio-frequency transmitter.
